(19) United States
(12) Patent Application Publication
(10) Pub. No.: US 2008/0042940 A1
(43) Pub. Date: Feb. 21, 2008

(54) Display device

(75) Inventor: Kazuhiro Hasegawa, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/889,409

(22) Filed: Aug. 13, 2007

(30) Foreign Application Priority Data
Aug. 21, 2006 (JP) 2006-224625

(51) Int. Cl. G09G 3/30

(52) U.S. Cl. 345/76; 345/55

(57) ABSTRACT

The invention provides a display device comprising a display unit, a circuit unit for driving the display unit and a bend suppressing member for suppressing bending of the display unit in a predetermined direction, the display unit comprising a flexible substrate and a display element having at least one layer of a display section interposed between a pair of upper and lower electrodes formed on the flexible substrate, the display unit being bendable in a direction perpendicular to the predetermined direction, one of the electrodes being made of a metal and the other electrode being made of a metal oxide formed into strips, and the longitudinal side of the electrode formed into strips being aligned in the predetermined direction for suppressing bending of the display unit.

### CROSS-REFERENCE TO RELATED APPLICATIONS

This application claims priority under 35 USC 119 from Japanese Patent Application No. 2006-224625, the disclosure of which is incorporated by reference herein.

### BACKGROUND OF THE INVENTION

1. Field of the Invention

The invention relates to a display device having a bendable display unit.

2. Description of the Related Art

While, conventionally, display devices such as data processing devices and televisions have principally used cathode ray tubes, flat display devices using, for example, a plasma display element, a liquid crystal display element or an electroluminescent element (hereinafter, “EL element”) have been developed in recent years for the purpose of saving space. However, since display elements were initially formed on a non-flexible (non-bendable) substrate such as a glass, it was extremely difficult to bend or fold the display device in the way that a paper sheet can be bent. In addition, caution is needed when handling a display unit using a glass substrate since such display units are readily broken by, for example, the impact of falling. Moreover, the weight of these devices has been increasing in accordance with the trend toward larger size screens.

Flexible display devices have been proposed in recent years in order to facilitate movement and portability. For example, a display device that can be rolled up into a rolled-screen configuration has been developed, and a display device which can be rolled-up and stored in a cylindrical container, have been proposed (for example, see Japanese Patent Application Laid-Open (JP-A) Nos. 2002-15858 and 2002-328625). A rollable structure of a flexible display device is obtained by forming a display element such as an EL element on a substrate having flexibility (a flexible substrate) such as a plastic sheet. In one example of a liquid crystal display element, a reinforcing member is provided so that the substrate is bendable in one direction but not bendable in a direction perpendicular to the bendable direction (see, for example, JP-A No. 6-347772).

### SUMMARY OF THE INVENTION

The invention has been made in view of the above circumstance and provides a display device.

A first aspect of the invention provides a display device comprising a display unit, a circuit unit for driving the display unit and a bend suppressing member for suppressing bending of the display unit in a predetermined direction, the display unit comprising a flexible substrate and a display element having at least one layer of a display section interposed between a pair of upper and lower electrodes formed on the flexible substrate, the display unit being bendable in a direction perpendicular to the predetermined direction, one of the electrodes being made of a metal while the other electrode being made of a metal oxide formed into stripes, and the longitudinal side of the electrode formed into strips being aligned in the predetermined direction for suppressing bending of the display unit.

### BRIEF DESCRIPTION OF THE DRAWINGS

FIG. 1 is a schematic perspective view showing an example of the constitution of the organic EL display device to which the invention is applied;

FIG. 2 is a plane view showing a main part of the constitution of the display unit and circuit unit of the organic EL display device to which the invention is applied;

FIG. 3 is a perspective view showing a main part of the constitution of the organic EL element provided in the organic EL display device to which the invention is applied;

FIG. 4 is a cross section showing a main part of the constitution of the organic EL element provided in the organic EL display device to which the invention is applied;

FIG. 5A is a schematic perspective view showing an example of the constitution of the organic EL display device provided with a display unit holding member to which the invention is applied;

FIG. 5B shows a cross section along the line A-A′ of the organic EL display device shown in FIG. 5A;

FIG. 6 is a cross section showing a main part of another example of the constitution of the organic EL element;

FIG. 7 is a cross section showing a main part of an example of the constitution of the inorganic EL element;

FIG. 8 is a cross section showing a main part of an example of the constitution of the microcapsular electrophoretic element;

FIG. 9 is a schematic perspective view showing an example of the constitution of the bend suppressing member applicable to the invention;

FIG. 10 is a schematic perspective view showing another example of the constitution of the bend suppressing member applicable to the invention;

FIG. 11 is a schematic perspective view showing a different example of the constitution of the bend suppressing member applicable to the invention;

FIG. 12 is a schematic perspective view showing a further different example of the constitution of the bend suppressing member applicable to the invention;

FIG. 13A is an example of the constitution of the bend suppressing member applicable to the invention having a structure for suppressing the amount of bending, and shows a schematic perspective view before bending;

FIG. 13B is an example of the constitution of the bend suppressing member applicable to the invention having a structure for suppressing the amount of bending, and shows a schematic perspective view after bending;

FIG. 14 is a schematic perspective view showing an example of the constitution of the bend suppressing member applicable to the invention having the structures for suppressing the amount of bending on both surfaces thereof;

FIG. 15A is an example of the constitution of the organic EL display device to which the invention is applied, and is a schematic perspective view during use;

FIG. 15B is an example of the constitution of the organic EL display device to which the invention is applied, and is a schematic perspective view showing the rolled and stored display unit;

FIG. 16A is an example of the constitution of an organic EL display device of a double-page spread type to which the invention is applied, and is a schematic perspective view during use; and

FIG. 16B is an example of the constitution of an organic EL display device of a double-page spread type to which the invention is applied, and is a schematic perspective view when the display unit is closed.

### DETAILED DESCRIPTION

A problem that occurs particularly in the display device using the flexible substrate but has not been supposed in the glass substrate is deterioration of durability of the display element caused by repeatedly applying bending stress to the substrate. No satisfactory proposal for solving the problem has been presented yet.

According to the invention, there is provided a display device being excellent in durability of the display element even when the display device is repeatedly bent for solving the above-mentioned problem.

Preferable embodiments of the invention will be described in detail with reference to the attached drawings.

The display device of the invention has a display unit, a circuit unit for addressing the display unit, and a bend suppressing member for suppressing bending of the display unit in a predetermined direction. The display unit has a flexible substrate and a display element having at least one layer of a display section between upper and lower electrodes formed on the flexible substrate. The display element is bendable in a direction perpendicular to the bend-suppressing direction. One of the electrodes (referred to as a first electrode hereinafter) is made of a metal while the other electrode (referred to as a second electrode) is made of a metal oxide formed into stripes, and the longitudinal side of the striped electrode is aligned in the predetermined direction for suppressing bending of the display unit.

The display device having an organic EL element as a display element will be described below.

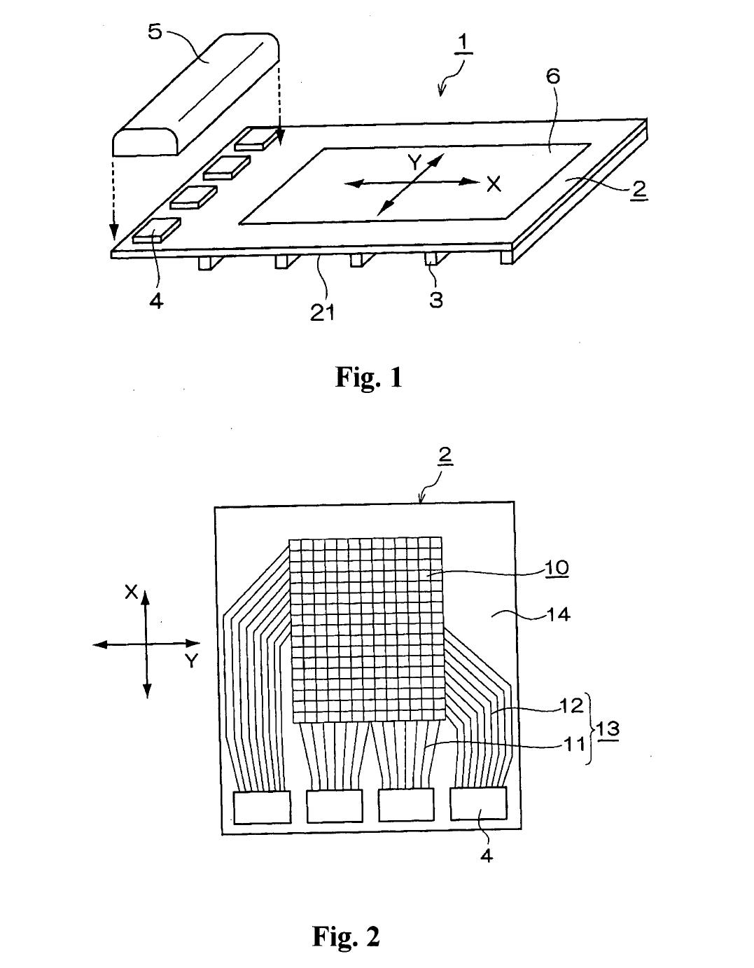

FIG. 1 is a schematic perspective view showing an example of the constitution of the organic EL display device to which the invention is applied. The organic EL display device 1 has a display unit 2 including a plastic film substrate 21 and an organic EL element 6 disposed on a surface side (display surface side) of the organic EL element 6, while an addressing circuit 4 for controlling addressing of the display unit 2 is disposed at one end of the plastic substrate 21 as a circuit unit for addressing the display unit 2. A power circuit (not shown) as a power source of the entire organic EL display device 1 and a signal processing circuit (not shown) for receiving display signals are also disposed. A circuit storage member 5 for storing the circuit unit 4 is disposed around the circuit unit 4.

Bend suppressing members 3 for suppressing bending of the display unit 2 in a predetermined direction are aligned on the back surface (non-display surface side) of the organic EL element 1 with a given distance apart. When XY directions are defined so that a longitudinal direction is in an X-direction and a transverse direction is in a Y-direction on the surface of the display device 2 shown in FIG. 1, the display unit 2 is bendable in the X-direction and is hardly bendable in the Y-direction due to the bend suppressing members 3 elongating in the Y-direction (the direction of the transverse side) and aligning in the X-direction (the direction of the longitudinal side) in parallel like teeth of a comb.

### [Display Member]

FIG. 2 is a plane view showing electric connection between the display unit 2 and addressing circuit 4. As shown in FIG. 2, the display unit 2 may be divided into a pixel unit 10 and wiring unit 14. The pixel unit 10 comprises the organic EL elements 6 arranged as a matrix on the plastic substrate. On the other hand, wiring lines 13 (longitudinal wiring lines 11 and transverse wiring lines 12) for electrically connecting each organic EL element and addressing circuit 4 for addressing respective organic EL elements are disposed in the wiring unit 14.

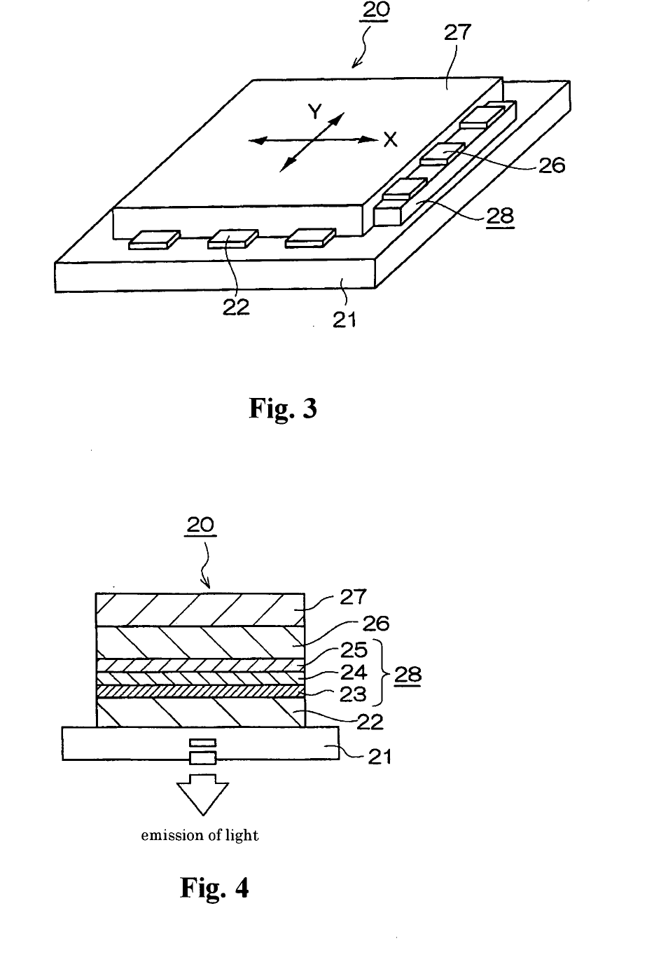

FIG. 3 is a perspective view showing the main part of the constitution of the organic EL element in the pixel unit 10. FIG. 4 is a cross section showing the main part thereof.

A plurality of positive electrodes 22 as transparent electrodes are provided on a transparent plastic film substrate 21 as stripes (belts) with a distance apart in the pixel unit 10, and are aligned in parallel so that the longitudinal side of the positive electrode 22 matches the Y-direction (the direction perpendicular to the X-direction as the bending direction) in which bending is suppressed. As shown in FIG. 4, a sheet of an organic EL layer 28 formed by sequentially laminating a hole transport layer 23, a luminescent layer 24 and an electron transport layer 25 is formed on the positive electrode 22. Stripes of a plurality of negative electrodes 26 are formed so as to be perpendicular to the positive electrode 22, and a protective layer 27 is provided thereon. The organic EL layer 28 as a display section is interposed at a position where the positive electrode 22 intersects the negative electrode 22 as the transparent electrode, or between a pair of the upper and lower electrodes 22 and 26.

While the amount of bending of the display unit 2 (pixel unit 10 and wiring unit 14) in the Y-direction is restricted by the bend suppressing member 3, the display unit is substantially bendable in the X-direction perpendicular to the positive electrode 22. “Substantially bendable in the X-direction” as used herein means that the amount of bending is larger in the X-direction than in the Y-direction. Since the positive electrodes 22 running in the Y-direction are formed as stripes with a distance apart to one another in the X-direction in the organic EL element 1 sown in FIGS. 1 to 3, substantially no bending stress is applied in the direction of the longitudinal side (Y-direction) of the stripe (positive electrode 22) when the display unit is bent in the X-direction.

The plastic film substrate and organic EL element constituting the display unit 2 will be specifically described below.

### <Plastic Film Substrate>

The plastic film substrate 21 serves as a support of the organic EL element 20, and layers 22 to 27 that constitute the organic EL element 20 are formed on the plastic film substrate 21. Another plastic film may be provided so as to cover the organic EL element 20 for protecting the organic EL element 20.

The material used for the plastic film substrate 21 is not particularly restricted so long as the material has a high transmittance. Preferable examples of the material include polyesters such as polyethylene terephthalate, polybutylene terephthalate and polyethylene naphthalate; and other plastic films such as polystyrene, polycarbonate, polyether sulfone, polyacrylate, polyimide, polycycloolefin, norbornene resin and poly(chlorotrifluoroethylene).

A gas barrier for preventing water and oxygen from permeating, a hard coat layer for preventing the organic EL element 20 from being damaged and an undercoat layer for improving planarity of the plastic film substrate 21 and adhesiveness of the substrate onto the positive electrode 22 may be provided on the plastic film substrate 21.

While the thickness of the plastic film substrate 21 may be appropriately determined depending on the materials and is not particularly restricted, it is preferably from 50 μm or more to 500 μm or less. The plastic film substrate 21 having a thickness in the above-mentioned range may maintain sufficient planarity as well as flexibility while the substrate 21 itself may be freely bent.

### <Positive Electrode>

The material used for the positive electrode 22 is not particularly restricted so long as it is able to supply holes to the organic EL layer 28 and functions as an electrode for transmitting a light from the organic EL layer, and may be appropriately selected from known electrode materials. Examples of the preferably used material include tin oxide (ATO, FTO) doped with antimony or fluorine, tin oxide, zinc oxide, indium oxide, indium tin oxide (ITO), zinc indium oxide (IZO) and zinc oxide doped with aluminum or gallium (AZO, GZO). ITO is more preferable as the positive electrode material used for the organic EL element in terms of injectability of holes, productivity, conductivity and transparency.

The thickness of the positive electrode 22 is preferably from 100 nm or more to 500 nm or less. The positive electrode 22 having the above-mentioned thickness may sufficiently function as a positive electrode while transmittance of visible light is sufficiently increased. The transmittance is preferably 60% or more, more preferably 70% or more. Resistivity of the positive electrode is preferably 10³Ω/square or less, more 10³Ω/square or less.

The metal oxide used for the positive electrode material has smaller bend strength as compared with the materials used for the negative electrode 26 to be described later. The “bend strength” as used herein refers to fracture strength when a bending stress is applied to the electrode. Brittle metal oxide materials have smaller bend strength than metals and alloys having large malleability.

### <Hole Transport Layer>

The hole transport layer 23 has a function for receiving holes from the positive electrode 22 and transporting them to the luminescent layer 24. While examples of the material used for the hole transport layer 23 include carbazole derivatives, triazole derivatives, oxazole derivatives, oxadiazole derivatives, imidazole derivatives, polyaryl alkane derivatives, pyrazoline derivatives, pyrazolone derivatives, phenylene diamine derivatives, aryl amine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, organic silane derivatives, carbon, phenylazole and various metal complexes represented by Ir complexes having phenylazine as ligands, the material is not restricted thereto.

### <Luminescent Layer>

The luminescent layer 24 has a function by which holes are received from the hole transport layer 23, electrons are received from the electron transport layer 25, and a recombination field between the electrons and holes is provided to emit a light. The luminescent layer 24 of the invention may be composed of either only a luminescent material or composed of a mixed layer of a host material and the luminescent material. The luminescent material may be either a fluorescent material or a phosphorescent material, and one or plural dopants may be used. The host material is preferably a charge transport material, and one or pluralities of host materials may be used, for example, an electron transporting host material and a hole transporting host material may be used by mixing them.

Examples of the fluorescent material applicable in the invention include benzoxazole derivatives, benzimidazole derivatives, benzothiazole derivatives, styryl benzene derivatives, polyphenyl derivatives, diphenyl butadiene derivatives, tetraphenyl butadiene derivatives, naphthalimide derivatives, coumalin derivatives, condensed aromatic compounds, perynone derivatives, oxadiazole derivatives, oxazine derivatives, aldazine derivatives, pyralidine derivatives, cyclopentadiene derivatives, bis-styryl anthracene derivatives, quinacridone derivatives, pyrrolopyridine derivatives, thiadiazolopyridine derivatives, cyclopentadiene derivatives, styrylamine derivatives, diketopyrrolopyrrole derivatives, aromatic dimethylidyne compound, various metal complexes represented by metal complexes of 8-quinolinol derivatives and pyrromethene derivatives, polymer compounds of polythiophene, polyphenylene and polyphenylenevinylene, and organic silane derivatives. However, the fluorescent material is not restricted thereto.

Examples of the phosphorescent material applicable in the invention include complexes containing transition metal atoms or lanthanoid atoms. While the transition metal atoms are not particularly restricted, examples of them preferably include ruthenium, rhodium, palladium, tungsten, rhenium, osmium, iridium and platinum, more preferably rhenium, iridium and platinum. Examples of the preferable lanthanoid atom include lanthanum, cerium, praseodymium, neodymium, samarium, europium, gadolinium, terbium, dysprosium, holmium, erbium, thulium, ytterbium and ruthenium; neodymium, europium and gadolinium are more preferable.

Examples of the ligand of the complex include halogen ligands (preferably chlorine ligands), nitrogen-containing heterocyclic ligands (such as phenyl pyridine, benzoquinoline, quinolinol, bipyridyl and phenanthroline), diketone ligands (such as acetylacetone), carboxylic acid ligands (such as acetic acid ligand), carbon monoxide ligand, isonitrile ligands and cyano ligands. The nitrogen-containing heterocyclic ligands are particularly preferable.

The luminescent layer 24 preferably contains from 0.1 to 40% by mass, more preferably from 5 to 20% by mass, of the phosphorescent material.

While examples of the host material contained in the luminescent layer 24 of the invention include those having carbazole frames, diarylamine frames, pyridine frames, pyrazine frames, triazine frames and arylsilane frames, and materials exemplified in the above-mentioned hole transport layer 23 and materials exemplified in the electron transport layer 25 to be described below, the host material is not restricted thereto.

### <Electron Transport Layer>

The electron transport layer 25 has a function for receiving electrons from the negative electrode 26 and transporting the electrons to the luminescent layer 24. Examples of the material used in the electron transport layer 25 include various metal complexes represented by metal complexes of triazole derivatives, oxazole derivatives, oxadiazole derivatives, imidazole derivatives, fluorenone derivatives, anthraquinodimethane derivatives, anthrone derivatives, diphenylquinone derivatives, thiopyran dioxide derivatives, carbodiimide derivatives, fluolenylidene methane derivatives, distyrylpyrazine derivatives, tetracarboxylic acid anhydride of aromatic rings such as naphthalene and perylene, phthalocyanine derivatives and 8-quinolinol derivatives; metal phthalocyanine, and metal complexes having benzoxazole and benzothiazole as ligands; and organic silane derivatives. However, the material is not restricted thereto.

### <Negative Electrode>

The negative electrode 26 is not particularly restricted so long as it has a function as an electrode for injecting electrons into the organic EL layer, and may be appropriately selected from known electrode materials. While examples of the material include metals and alloys, the metals are preferable. Specific examples of the metal include those having a low work function such as alkali metals (for example Li, Na, K, Cs), alkali earth metals (for example Mg, Ca), gold, silver, lead, aluminum, sodium-potassium alloy, lithium-aluminum alloy, magnesium-silver alloy, and rare earth metals such as indium and ytterbium. However, the material is not restricted thereto.

### <Protective Layer>

The materials of the protective layer 27 is not particularly restricted so long as it has a function for suppressing element-deteriorating substances such as water and oxygen from invading into the element, and may be appropriately selected from known materials. Examples of the material include metals such as In, Sn, Pb, Au, Cu, Ag, Al, Ti and Ni; metal oxides such as MgO, SiO, SiO₂, Al₂O₃, GeO, NiO, CaO, BaO, Fe₂O₃, Y₂O₃ and TiO₂; metal nitrides such as SiNₓ and SiNₓO_{y}; metal fluorides such as MgF₂, LiF, AlF₃ and CaF₂; polyethylene, polypropylene, methyl polymethacrylate, polyimide, polyurea, polytetrafluoroethylene, polychlorotrifluoroethylene, polydichlorodifluoroethylene, a copolymer of chlorotrifluoroethylene and dichlorodifluoroehtylene, a copolymer obtained by copolymerization of tetrafluoroethylene and a monomer mixture containing at least one commoner, a fluorine-containing copolymer having a cyclic structure at the copolymer main chain, a substance having 1% or more .of water absorption coefficient, and a moisture preventive substance having 0.1% or less of water absorption coefficient. However, the material is not restricted thereto.

The pixel unit 10 is formed with the plastic film substrate 21 and organic EL element 20, or the positive electrode 22, hole transport layer 23, luminescent layer 24, electron transport layer 25 and negative electrode 26. When a direct current voltage is selectively applied between the positive electrode 22 and negative electrode 26 of the organic EL element 20, the holes injected from the positive electrode 22 are transported through the hole transport layer 23, the electrons injected from the negative electrode 26 are transported through the electron transport layer 25, and the electrons and holes arrive at the luminescent layer 24. Consequently, the electrons and holes are re-combined in the luminescent layer 24, which emits a light with a predetermined wavelength. The organic EL element may function as a full color display element or a multicolor pixel unit that emits three colored light of R, G and B.

The wiring unit 14 has two kinds of wiring lines, or wiring lines 13 comprising longitudinal wiring lines 11 pulled out of the negative electrodes 26 and transverse wiring lines 12 pulled out of the positive electrodes 22 of the organic EL element 20.

The longitudinal wiring lines 11 are pulled out of the negative electrodes 26, and are aligned on the display unit 2 (plastic film substrate 21) in the X-direction, or in a direction perpendicular to the addressing circuit 4. The longitudinal wiring lines 11 are directly and approximately linearly aligned to the respective circuit units (addressing circuits 4) from the respective pixel units 10, and connect between each organic EL element 20 and addressing circuit 4.

On the other hand, the transverse wiring lines 12 are pulled out of the positive electrodes 22, and are pulled out in the direction of the circuit units (addressing circuits 4) with an angle of 45° to the direction parallel to the addressing circuits 4 on the display unit 2 (plastic film substrate 21). The transverse wiring lines 12 are then approximately linearly aligned toward the addressing circuits 4, and connect between the organic EL elements 20 and each addressing circuit 4.

The transverse wiring lines 12 are pulled out in both directions by approximately halving the pixel units 10 in FIG. 2. The pixel unit 10 may be disposed approximately at the center of the display unit 2 by pulling the transverse wiring lines 12 in both directions of the pixel unit 10. However, the transverse wiring lines 12 are not necessarily required to be pulled out in both directions of the pixel unit 10, instead the transverse wiring lines 12 may be pulled out in one arbitrary direction of the pixel unit 10.

Examples of the materials of the longitudinal wiring lines 11 and transverse wiring lines 12 include Au, Cr, Al and Cu that have low resistivity and chemically stable.

### [Bend Suppressing Member]

Plural rods of the bend suppressing member 3 are directly disposed on the back face of the display unit 2 in FIG. 1. Since bending in the Y-direction is restricted by separately disposing the plural bend suppressing members 3, it is preferable that the space between the adjoining bend suppressing members 3 is small, and rigidity of the bend suppressing members 3 is preferably higher than the rigidity of the plastic film substrate 21.

The material of the bend suppressing members 3 is not particularly restricted so long as it has a function for suppressing bending of the display unit 2, and may be appropriately selected from known materials. Examples of the material include metals, plastics, woods, paper sheets and ceramics.

The bend suppressing member 3 may be disposed by bonding a rod member made of the above-mentioned material on the back face side of the plastic film substrate 21 of the display unit 2, or by hardening a thermosetting resin or light-curable resin into the pattern of the bend suppressing member 3 after coating the resin on the back surface side of the plastic film substrate 21.

The direction of the longitudinal side of the stripes of the positive electrode 22 of the pixel unit 10 and the bend restricting direction of the bend restricting structure 3 are determined to be the same direction as the direction perpendicular to the bending direction X in the display unit 2 so constructed as described above. Accordingly, substantially no bending tress is applied to the positive electrode 22 when the display unit 2 is bent. Consequently, stable display of the display unit is possible for a long period of time even by repeatedly bending the display unit.

While the angle between the bending direction (X-direction) and the longitudinal direction (Y-direction) of the stripes of the positive electrode 22, and the angle between the bending direction and the bend suppressing direction of the bend suppressing member 3 are 90°, or the former angles are perpendicular to the latter angles, in the description above, these angles are not always 90° to one another in the organic EL display device according to an embodiment of the invention.

For example, it is possible to obtain an effect for preventing the positive electrode 22 to be broken even when the angle is slightly aslant from 90° due to a production error. It is also possible to permit the positive electrode to be aslant depending on the array of the pixels instead of aligning the positive electrode to be perpendicular to the negative electrode in a passive matrix display element, when the pixels are arranged in a delta shape for obtaining high quality image display. The angle between the positive electrode and negative electrode may be in the range from 10° to 30°. Accordingly, the perpendicular direction defined in the invention is 90°±30° from the above-mentioned point of view.

### [Circuit Unit]

The circuit unit is disposed at one end of the display unit 2, and include addressing circuit 4 for controlling addressing of the organic EL element 20, a power source circuit (not shown) for supplying electric power to the entire organic EL display device 1, and a signal processing circuit (not shown) for receiving display signals.

A circuit storage member 5 covering the circuits is also provided. The circuit storage member 5 protects the circuits while it serves as an axis for rolling and storing the display unit 2. While the shape of the circuit storage member 5 may be a rectangular column or round cylindrical column, a round shape is preferable in order to prevent the surface of the display unit 2 from being damaged or from suffering from an uneven stress when the display unit 2 is rolled and stored. The diameter or cross-sectional size of the circuit storage member 5 is preferably determined to be a sufficient size by taking the mechanical strength of the material constituting the display unit 2 into consideration in terms of the function as the axis for rolling and storing the display unit 2.

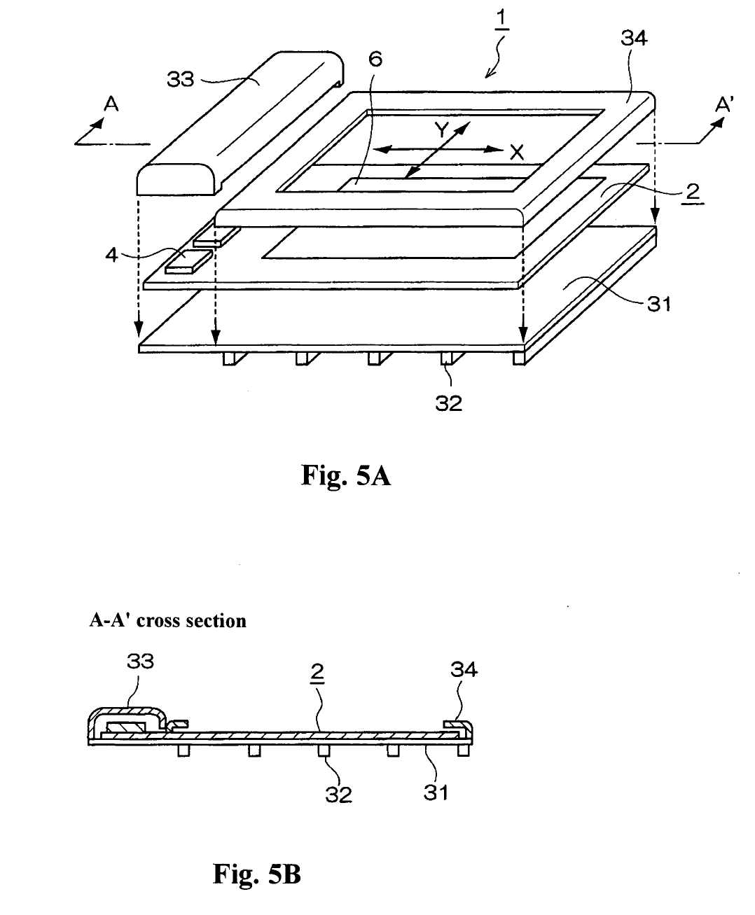

As shown in FIGS. 5A and 5B, the organic EL display device 1 is preferably provided with display unit holding members 31 and 34 for holding the display unit 2. The display unit 2 is held so that it is inserted between the upper and lower holding members 31 and 34. The display unit holding member 31 is disposed at the non-display surface side of the display member 2, and the bend suppressing member 32 is disposed on the back surface of the holding member 31. The other display unit holding member 34 is disposed at the display surface side of the display unit 2, and has an opening corresponding to the display area (pixel unit 10) of the display unit 2. These display unit holding members 31 and 34 are formed of a flexible material, and the display unit 2 of the organic EL display device 1 is able to be bent in the X-direction even when the display unit holding members 31 and 34 is attached to the display unit. In addition, the display unit 2 and display unit holding members 31 and 34 are freely slidably engaged to one another in the X-direction, or in the bending direction of the display unit in the organic EL display device 1 shown in FIG. 5. Accordingly, the display unit 2 is movable between the display unit holding members 31 and 34 so that the stress applied to the display unit by bending the organic EL display device 1 may be relaxed.

The material of the display unit holding members 31 and 34 is not particularly restricted, and may be appropriately selected from known materials such as metals, plastics, paper sheets and leathers.

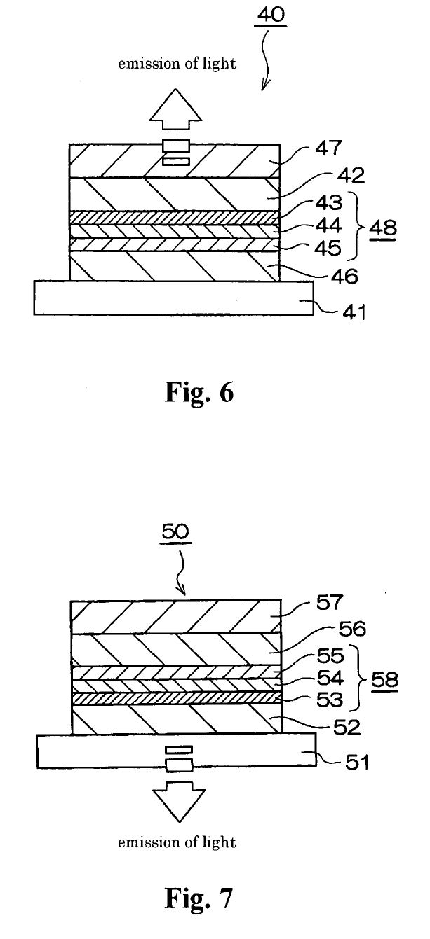

The organic EL display device 1 may be constructed so that luminescence of the organic EL element 20 is emitted from the protective layer 27 side. The construction of the electrodes and organic EL layer in this case is reversed from the construction using the organic EL element 20 in which luminescence is emitted from the plastic film substrate side, and the organic EL element 40 has a construction as shown in FIG. 6. The organic EL, element 40 has a negative electrode 46 formed on a substrate 41, and an electron transport layer 45, a luminescent layer 44 and a hole transport layer 43 are sequentially formed thereon as an organic EL layer 48. A positive electrode 42 is formed on the organic EL layer 48, and a protective layer 47 is formed on the positive electrode 42.

The positive electrode 42 of the pixel unit 10 is aligned in a direction perpendicular to the bending direction in the display unit 2 having the organic EL element 40 so constructed as described above. Accordingly, no substantial stress is applied to the positive electrode 42 when the display unit 2 is bent. Consequently, the positive electrode 42 is prevented from being broken even by repeating rolling and storage of the display unit 2, and stable display of the display unit 2 is possible for a long period of time.

While any substrates including a plastic film substrate may be used as the substrate 41 so long as it is flexible, a flexible and opaque substrate such as a metal film substrate may be used since luminescence from the organic EL element 40 is not required to be emitted through the substrate. The metal film substrate is preferable since it has a higher gas barrier property than the plastic film substrate. However, an additional insulation layer for maintaining electric insulation between the adjoining negative electrodes 46 is necessary between the substrate 41 and negative electrode 46 when a metal film is used as the substrate of the organic EL element 40.

Any metals such as stainless steel, Fe, Al, Ni, Co and Cu, and alloys thereof capable of forming into a film at an ambient temperature and pressure may be used as the material used for the metal film substrate 41.

While the organic EL display devices having the pixel unit 10 composed of the organic EL element 20 and 40 have been described above, the EL display device according to an embodiment of the invention is not restricted to these display devices. Instead, an inorganic EL display device having the pixel unit 10 made of an inorganic EL element may also be available.

The inorganic EL display device has a pixel unit formed by arranging a large number of inorganic EL elements into a matrix. FIG. 7 shows a longitudinal cross section showing the main part of the construction of the inorganic EL element 50. A plurality of first electrodes 52 as striped transparent electrodes are formed on a plastic film substrate 51 that serves as a transparent substrate in the pixel unit of the inorganic EL display device, and a sheet of inorganic EL layer 58 having a first dielectric layer 53, a luminescent layer 54 and a second dielectric layer 55 is laminated on the first electrode. A plurality of striped second electrodes 56 as reflection electrodes are provided so as to be perpendicular to the first electrodes 52, and a protective layer 57 is formed on the second electrodes 56. Such construction permits the inorganic EL layer 58 as a display section to be interposed at the position where the first electrode 52 and second electrode 56 as a transparent electrode intersect to one another, or between the upper and lower electrodes 52 and 56.

The material preferably used for the luminescent layer 54 includes a sulfide such as ZnS, CaS, SrS or BaAl₂S₄ as a base material into which a transition metal such as Mn or Cu or a rare earth element such as Eu, Ce, Tb, Er, Tm or Sm is added as a dopant.

The materials preferably used for the first dielectric layer 53 and second dielectric layer 55 are materials having a high dielectric constant such as Y₂O₃, Ta₂O₅, TiO₂, BaTiO₃ and SrTiO₃.

The material preferably used for the first electrode 52 is a. material having a high transmittance such as ITO, IZO, AZO or GZO.

The material preferably used for the second electrode 56 is a metal having high reflectivity such as Al, Cr, Au or Ag, or an alloy thereof.

The flexible substrate is not restricted to the above-mentioned plastic film substrate 51, and an opaque substrate such as a metal film substrate may be used. Since the metal film substrate has higher heat resistance than the plastic film substrate, the former is preferably used for forming the luminescent layer 54 and dielectric layers 53 and 55 that require a high temperature of the substrate for film deposition. When the metal film substrate is used as the substrate of the inorganic EL element 50, the positional relation of the first electrode 52 and second electrode 56 is reversed so that luminescence from the inorganic EL layer 58 is emitted from the protective layer 57 side, and it is necessary to further provide an insulation layer for maintaining electric insulation between the adjoining second electrodes 56 between the substrate 51 and second electrode 56.

In the display unit 2 having the inorganic EL element 50 so constructed as described above, the first electrodes 52 of the pixel unit 10 are aligned in a direction perpendicular to the bend direction as in the organic EL element. Accordingly, substantially no bending stress is applied to the first electrode 52 even by bending the display unit 2, and consequently the first electrode 52 is prevented from being broken due to repeated bending so that stable display is possible for a long period of time at the display unit.

While the EL display device having the pixel unit 10 composed of the organic or inorganic EL element 20 has been described above, the display element of the display device according to an embodiment of the invention is not restricted to the luminescent element such as the EL element, and elements that emit a light or change optical characteristics depending on the applied electric field may also be used. For example, the display device may be an electrophoresis display device in which the pixel unit 10 is composed of electrophoretic elements.

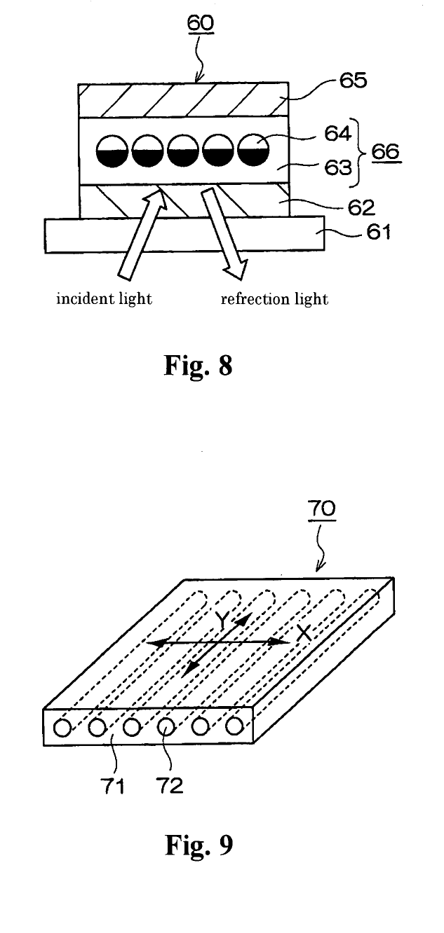

The electrophoresis display device has a pixel unit in which a large number of electrophoretic elements are arranged as a matrix. FIG. 8 shows a longitudinal cross section of the main part of the constitution of the electrophoretic element 60. The pixel unit of the electrophoresis display device comprises, for example, a plurality of first electrodes 62 as striped transparent electrodes formed on a plastic film substrate 61 as a transparent substrate, and a display layer 66 is provided on the first electrode 62. The display layer 66 comprises a dielectric layer 63 and microcapsules 64 that are dispersed in the dielectric layer 63 and contain two kinds of pigments each having different charges and colors. A plurality of striped second electrodes 65 as reflection electrodes are provided so as to be perpendicular to the first electrode 62. The electrophoretic element 60 having such construction permits the display layer 66 as a display section to be interposed at a position where the first electrode 62 as the transparent electrode intersects the second electrode, or between the upper and lower electrodes 62 and 65.

In the display unit 2 having the electrophoretic element 60 so constructed as described above, the first electrode 62 of the pixel unit 10 is aligned in the direction perpendicular to the bend direction as in the organic EL element. Accordingly, substantially no bending stress is applied to the first electrode 62 even by bending the display unit 2, and consequently the first electrode 62 is prevented from being broken due to repeated bending so that stable display is possible for a long period of time at the display unit.

While a passive matrix flexible display device comprising the pixel unit composed of the EL element or electrophoretic element has been described above, the invention is not restricted thereto. The invention may also be applied to a flexible display device using a metal oxide for the wiring line or as a material of one of the striped display electrodes of the display element.

While the flexible display device having rods of the bend suppressing member has been described above, the invention is not restricted thereto, and may be applied to the flexible display device using the bend suppressing members having various shapes and constructions. For example, the bend suppressing member may be provided at least at a part of the flexible substrate or display unit holding member.

FIG. 9 is a schematic perspective view showing the constitution of a plate member 70 having pluralities of round columnar bend suppressing members 72 embedded in a resin matrix 1. The plate member 70 may be obtained, for example, by integrating round columnar bend suppressing members 72 such as a highly rigid metal wires and a resin member 71 using a cast method. This structure permits the plate member 70 to be bendable in the X-direction and hardly bendable in the Y-direction. Such plate member 70 may be used as a flexible substrate of the display element and display unit holding member of the flexible display device.

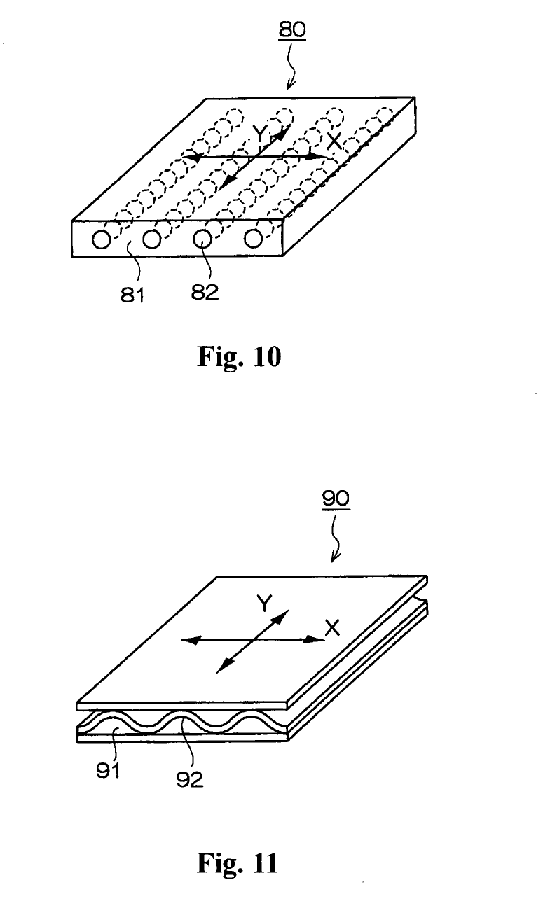

FIG. 10 is a schematic perspective view showing the constitution of a plate member 80 having pluralities of spherical bend suppressing members 82 embedded in a resin matrix 81 as an array. Such plate member 80 may be obtained, for example, by integrating highly rigid spherical bend suppressing members 82 such as glass beads and a resin member 81 using a cast method. This structure permits the plate member 80 to be bendable in the X-direction and hardly bendable in the Y-direction. Such plate member 80 may also be used as a flexible substrate of the display element and display unit holding member of the flexible display device.

FIG. 11 is a schematic perspective view showing the constitution of a plate member 90 having a corrugate sheet of a bend suppressing member 92 interposed between two plate members 91. This plate member 90 may be obtained, for example, by integrating the corrugate sheet of the bend suppressing member 92 formed by pressing a metal plate and the plate member 91 by bonding or welding. This construction permits the plate member 90 to be bendable in the X-direction and hardly bendable in the Y-direction. Such plate member 90 may also be used as a flexible substrate of the display element and display unit holding member of the flexible display device.

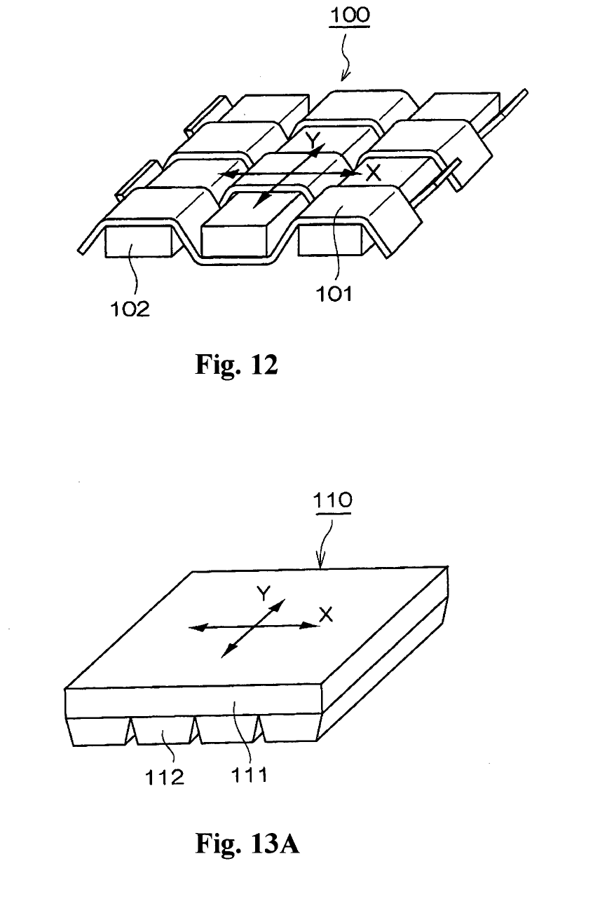

FIG. 12 is a schematic perspective view showing the constitution of a plate member 100 formed by knitting pluralities of rods of the bend suppressing members 102 with flat strings 101. This construction permits the plate member 100 to be bendable in the X-direction and hardly bendable in the Y-direction. Such plate member 100 may also be used as a display unit holding member of the flexible display device.

While the bend suppressing members having various structures and shapes have been described above, the flexible display device of the invention preferably has an additional structure for restricting the amount of bending of the bend suppressing member.

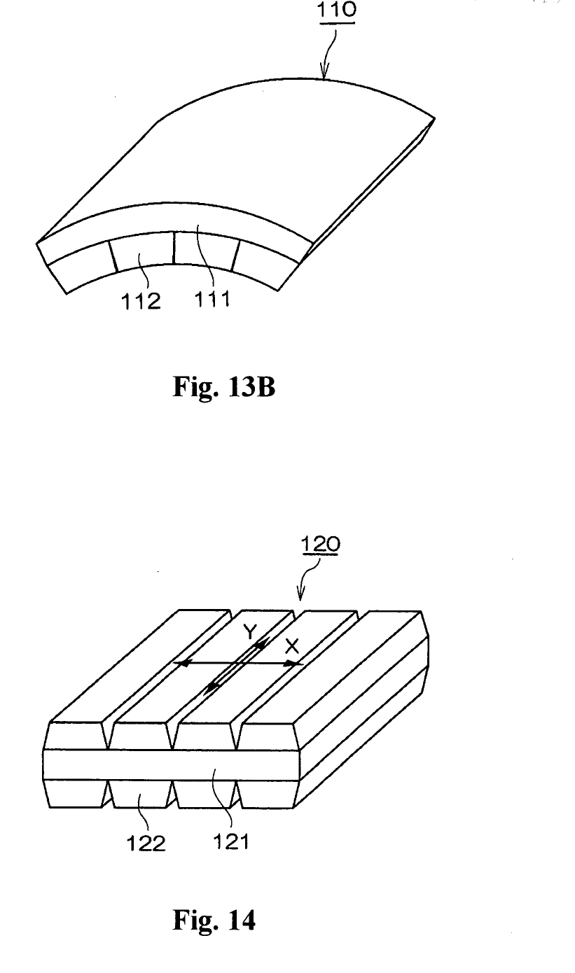

FIG. 13A is a schematic perspective view showing the constitution of a plate member 110 in which pluralities of rods of the bend suppressing members 112 having a trapezoidal cross section are disposed on a plate member 111 so that the trapezoidal rods adjoin to one another. FIG. 13B is a schematic perspective view showing a bent state of the plate member 110. FIG. 13 shows that the plate member 110 is not bendable any more when the bend suppressing members 112 are in contact to one another. This construction permits the plate member 110 to be bendable in the X-direction in a predetermined amount, and hardly bendable in the Y-direction. When an organic EL display device is formed by applying the plate member 110 to the flexible substrate or display unit holding member, the members other than the positive electrode 22 is hardly deteriorated by repeating bending operations, while more stable display is possible for a long period of time.

FIG. 14 is a schematic perspective view showing a constitution of a plate member 120 in which pluralities of rods of the bend suppressing members 122 having a trapezoidal cross section are disposed in an adjoining relation to one another on both surfaces of a plate member 121. This construction permits the plate member 120 to be bendable in a predetermined amount on both the upper and lower surfaces in the X-direction, and hardly bendable in the Y-direction. The plate member 120 may be used as a display unit holding member of the flexible display device.

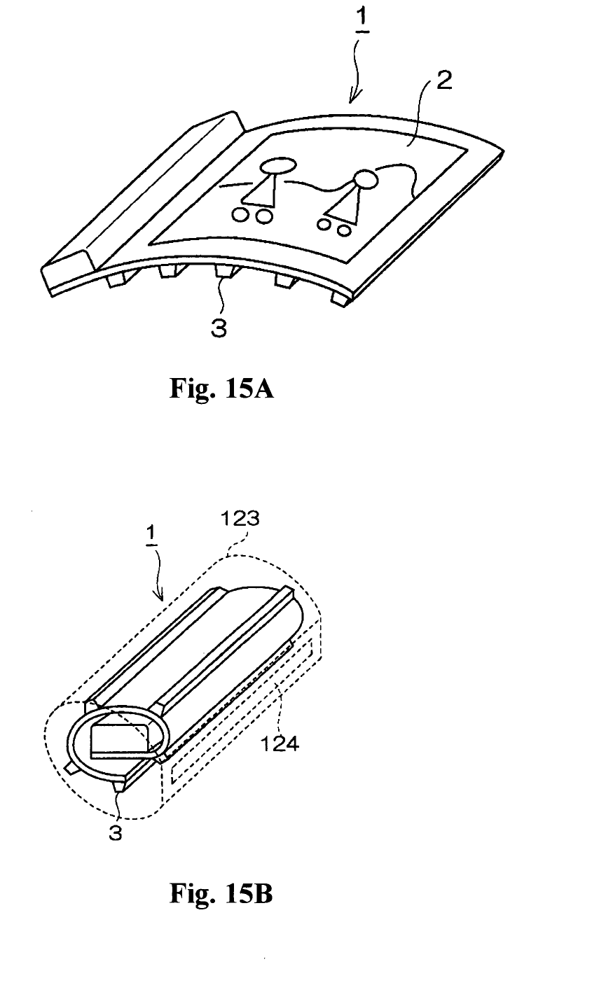

The flexible display device of the invention may be applied to various forms of electronic media. For example, the display device may comprise a storage unit for storing the display unit 2. FIG. 15A is a schematic perspective view showing a rollable organic EL display device 1 during use. FIG. 15B is a schematic perspective view of the display device where the display unit 2 is rolled and stored in a case 123. The display unit 2 is able to be pulled out through an opening 124 of the case 123, or the display unit 2 is able to be rolled and stored in the case 123 and to be pulled out from the case 123. Since bending in a predetermined direction is restricted by a bend suppressing member 3 when the display unit 2 is rolled and stored as shown in FIG. 15B or when the display unit 2 is pulled out from the case as shown in FIG. 15B, the positive electrode 22 is not broken so that stable display of the display unit is possible for a long period of time.

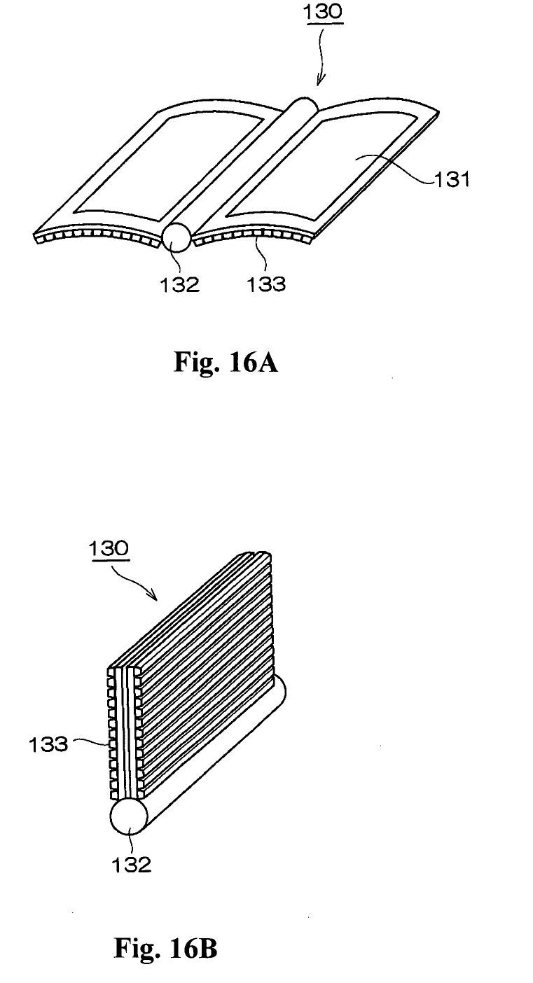

FIG. 16A is a schematic perspective view of a flexible display device 130 of a double-page spread type during use, and FIG. 16B is a schematic perspective view of the flexible display device 130 of a double-page spread type when closed. Two display units 131 are joined with a circuit unit 132 that serves as a hinge in the flexible display device 130 of a double-page spread type, and the display units may be opened and closed using the circuit unit 132 as an axis. Pluralities of bend suppressing members 133 capable of restricting the amount of bending are disposed in adjoining relation to one another on the non-display surface of the display unit 131, and the display unit 131 is bendable in a predetermined amount. Since this construction is able to be approximately equally balanced in the right and left directions when the display unit 131 is bent so that the display device is readily manipulated by holding the flexible display device hand, handling ability of the device may be quite high.

While the passive matrix flexible display device having the pixel unit composed of the EL element or electrophoretic element has been described above, the invention is not restricted thereto. The invention may be applied to a flexible display device having a display element using a metal oxide for the wiring lines or for the material of one of the striped display electrodes.

When the longitudinal side of the striped electrode is aligned in a predetermined direction (the bend suppressing direction) as described above, substantially no bending stress is applied to the striped electrode in the direction of stripes (direction of the longitudinal side) even by repeating to bend. Accordingly, the electrode is prevented from being broken and stable display is possible for a long period of time. Consequently, the screen may be large size while the display device is small size and light weight, and a display device durable to the shock of falling may be provided.

Since the display device of the invention is able to suppress bending stress applied to the display element by repeated bending to consequently prevent the display element, or particularly the electrode, from being broken, stable display of the image is possible for a long period of time. Since the direction of the longitudinal side of the electrode formed into strips is aligned in the same direction as the bend suppressing direction of the bend suppressing member, bending stress may be effectively prevented from being applied when the display unit (display element) is bent so that stable display is possible for a long period of time.

The display device according to an embodiment of the invention may be favorably used, for example, for a large screen display capable of rolling and storing the display unit and capable of pulling out the stored display unit. Storing the display unit enables the space of the storage site to be saved, while rolling and pulling out of the display unit may be facilitated by permitting the bend suppressing member to restrict the display member from being bent in a predetermined direction. In addition, the display unit is not excessively bent by permitting the bend suppressing member to restrict the amount of bending in the bending direction, so that the display device may be readily manipulated by hand and readable.

<1> A display device comprising a display unit, a circuit unit for driving the display unit and a bend suppressing member for suppressing bending of the display unit in a predetermined direction, the display unit comprising a flexible substrate and a display element having at least one layer of a display section interposed between a pair of upper and lower electrodes formed on the flexible substrate, the display unit being bendable in a direction perpendicular to the predetermined direction, one of the electrodes being made of a metal while the other electrode being made of a metal oxide formed into stripes, and the longitudinal side of the electrode formed into strips being aligned in the predetermined direction for suppressing bending of the display unit.

<2> The display device of item <1> further comprising a display unit holding member for holding the display unit.

<3> The display device of item <2>, wherein the display unit is freely slidably engaged with the display unit holding member.

<4> The display device of any one of items <1> to <3>, wherein the bend suppressing member is provided at least a part of the flexible substrate or the display unit holding member.

<5> The display device of any one of items <1> to <4>, wherein there are plural bend suppressing members, and wherein the amount of bending of the display unit is restricted by allowing adjacent bend suppressing members to contact one another when the display unit is bent.

<6> The display device of any one of items <1> to <5>, wherein the display element emits a light or changes optical characteristics by application of an electric field.

<7> The display device of any one of items <1> to <6>, wherein the display element is a luminescent element.

<8> The display device of any one of items <1> to <7>, wherein the display element is a organic electro luminescent element.

<9> The display device of any one of items <1> to <7> further comprising a storage unit for storing the display unit.

<10> The display device of any one of items <1> to <8>, wherein the storage unit stores the display unit once the display unit has been rolled up, and the stored display unit can be pulled out from the storage unit.

<11> A display device comprising a display unit, a circuit unit for addressing the display unit and a bend suppressing member for suppressing bending of the display unit in a predetermined direction, the display unit comprising a flexible substrate and an organic EL element having at least one layer of a display section interposed between a pair of upper and lower electrodes formed on the flexible substrate, the display unit being bendable in a direction perpendicular to the predetermined direction, one of the electrodes being made of a metal while the other electrode being made of a metal oxide formed into stripes, and the longitudinal side of the electrode formed into strips being aligned in the predetermined direction for suppressing bending of the display unit.

All publications, patent applications, and technical standards mentioned in this specification are herein incorporated by reference to the same extent as if each individual publication, patent application, or technical standard was specifically and individually indicated to be incorporated by reference.

It will be obvious to those having skill in the art that many changes may be made in the above-described details of the preferred embodiments of the present invention. The scope of the invention, therefore, should be determined by the following claims.

What is claimed is:

1. A display device, comprising a display unit, a circuit unit for driving the display unit and a bend suppressing member for suppressing bending of the display unit in a predetermined direction,
the display unit comprising a flexible substrate and a display element having at least one layer of a display section interposed between a pair of upper and lower electrodes formed on the flexible substrate,
the display unit being bendable in a direction perpendicular to the predetermined direction,
one of the electrodes being made of a metal and the other electrode being made of a metal oxide formed into strips, and
the longitudinal side of the electrode formed into strips being aligned in the predetermined direction for suppressing bending of the display unit.

2. The display device of claim 1, further comprising a display unit holding member for holding the display unit.

3. The display device of claim 2, wherein the display unit is freely slidably engaged with the display unit holding member.

4. The display device of claim 1, wherein the bend suppressing member is provided at at least a part of the flexible substrate or the display unit holding member.

5. The display device of claim 2, wherein the bend suppressing member is provided at at least a part of the flexible substrate or the display unit holding member.

6. The display device of claim 3, wherein the bend suppressing member is provided at at least a part of the flexible substrate or the display unit holding member.

7. The display device of claim 1, wherein there are plural bend suppressing members, and wherein the amount of bending of the display unit is restricted by allowing adjacent bend suppressing members to contact one another when the display unit is bent.

8. The display device of claim 2, wherein there are plural bend suppressing members, and wherein the amount of bending of the display unit is restricted by allowing adjacent bend suppressing members to contact one another when the display unit is bent.

9. The display device of claim 3, wherein there are plural bend suppressing members, and wherein the amount of bending of the display unit is restricted by allowing adjacent bend suppressing members to contact one another when the display unit is bent.

10. The display device of claim 4, wherein there are plural bend suppressing members, and wherein the amount of bending of the display unit is restricted by allowing adjacent bend suppressing members to contact one another when the display unit is bent.

11. The display device of claim 1, wherein the display element emits a light or changes optical characteristics by application of an electric field.

12. The display device of claim 1, wherein the display element is a luminescent element.

13. The display device of claim 1, further comprising a storage unit for storing the display unit.

14. The display device of claim 14, wherein the storage unit stores the display unit once the display unit has been rolled up, and the stored display unit can be pulled out from the storage unit.

15. A display device, comprising a display unit, a circuit unit for driving the display unit and a bend suppressing member for suppressing bending of the display unit in a predetermined direction,
the display unit comprising a flexible substrate and an organic EL element having at least one layer of a display section interposed between a pair of upper and lower electrodes formed on the flexible substrate,
the display unit being bendable in a direction perpendicular to the predetermined direction,
one of the electrodes being made of a metal and the other electrode being made of a metal oxide formed into strips, and
the longitudinal side of the electrode formed into strips being aligned in the predetermined direction for suppressing bending of the display unit.
